(19) United States
(12) Patent Application Publication
(10) Pub. No.: US 2010/0103288 A1
(43) Pub. Date: Apr. 29, 2010

(54) Image sensor

(75) Inventors: Jung Chak AHN, Yongin-si (KR); Tae Sub JUNG, Anyang-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/588,035

(22) Filed: Oct. 1, 2009

(30) Foreign Application Priority Data
Oct. 28, 2008 (KR) 10-2008-0105772

(51) Int. Cl. H04N 5/76; H04N 5/335

(52) U.S. Cl. 348/231.99; 348/273; 348/E05.091; 348/E05.031

(57) ABSTRACT

Provided is an image sensor. The image sensor includes a first pixel. The image sensor may include a second pixel formed to be adjacent to the first pixel. The pixel includes a first photoelectric conversion unit formed on a semiconductor substrate and generates charges according to incident light. A first color filter formed over the first photoelectric conversion unit guides light through the first color filter to the first photoelectric conversion unit corresponding to the color filter. The image sensor includes at least one light reflection pattern formed reflecting externally-incident light to the first or second pixel corresponding to the at least one light reflection pattern.

### FOREIGN PRIORITY STATEMENT

This application claims the benefit of Korean Patent Application No. 10-2008-0105772, filed on Oct. 28, 2008, in the Korean Intellectual Property Office, the disclosure of which is incorporated herein in its entirety by reference.

### BACKGROUND

Example embodiments relate to image sensors, and more particularly, to a complementary metal oxide semiconductor (CMOS) image sensor.

Image sensors are devices that convert an optical image into an electrical signal. With recent developments of a computer industry and a communication industry, a demand for CMOS image sensors having improved performances is increasing in various fields such as digital cameras, camcorders, personal communication systems (PCSs), game players, security cameras, medical micro cameras, and robots.

CMOS image sensors may include a photo diode for sensing externally-incident light, and a circuit for converting the sensed light into an electrical signal and digitizing the electrical signal. As the amount of light received by the photo diode increases, the photo sensitivity of the CMOS image sensors increases. Such a CMOS image sensor may include a plurality of photodiodes formed on (or on) a semiconductor substrate, a plurality of color filters formed to correspond to the photodiodes in order to pass light in specific wavelengths, and a plurality of lenses formed to correspond to the color filters.

Light externally incident on the CMOS image sensor may be focused by the lenses, be filtered by the color filters, and be incident on the photo diodes formed to correspond to the color filters. However, in the above-described CMOS image sensor, due to light diffraction, light passed through the color filters is not incident on their respective photo diodes but incident on adjacent photodiodes. Accordingly, cross-talk or the like is generated, thereby increasing light loss and degrading the characteristics of the CMOS image sensor.

### SUMMARY

Example embodiments provide an image sensor capable of reducing (or alternatively preventing) cross-talk. The present invention also provides an image sensing system using the image sensor.

Image sensors according to some embodiments include a charge coupled device (CCD) image sensor or a complementary metal oxide semiconductor (CMOS) image sensor. The CCD image sensor generates small noise and provides a high-quality image, as compared with the CMOS image sensor. However, the CCD image sensor requires a high voltage and is manufactured at high costs. The CMOS image sensor is simply driven and can be implemented according to various scanning methods. Since signal processing circuits can be integrated into a single chip, the CMOS image sensor can be made compact. In addition, the CMOS image sensor can compatibly use a CMOS process technique, thus reducing the manufacturing costs of CMOS image sensors. Moreover, the CMOS image sensor consumes very small power and accordingly is easily applied to products that have limits in battery capacity. Thus, such a CMOS image sensor is illustrated as the image sensors according to some embodiments. However, the technical spirit of the present invention may also be applied to CCD image sensors.

According to at least one aspect of an embodiment, there is provided an image sensor including a first pixel and a second pixel formed to be adjacent to the first pixel. The image sensor further includes at least one light reflection pattern formed between the first and second pixels and reflecting externally-incident light to the first or second pixel corresponding to the at least one light reflection pattern.

Each of the first and second pixels include a photoelectric conversion unit formed on a semiconductor substrate and generates charges according to light incident from an external source; a color filter formed over the photoelectric conversion unit. The first and second pixels include an optical guide located between the photoelectric conversion unit and the color filter and guiding light incident from the external source via the color filter to the photoelectric conversion unit that faces the color filter.

At least one light reflection pattern reflects light incident from the external source and refracted by the color filter of the first pixel or the color filter of the second pixel so that the refracted light is incident on the optical guide of the first pixel or the optical guide of the second pixel.

According to another embodiment, there is provided an image sensor including a first pixel and at least a first light reflection pattern formed adjacent to the first pixel. The first light reflection pattern reflects incident light to the pixel. The first pixel includes a first photoelectric conversion unit formed on a semiconductor substrate and generates charges according to incident light. Also, first a color filter may be formed over the first photoelectric conversion unit. The pixel also includes a first optical guide located between the first photoelectric conversion unit and the first color filter and guides light through the first color filter to the first photoelectric conversion unit corresponding to the first color filter. Additionally, at least the first light reflection pattern reflects light refracted by a the first color filter so that the refract light is incident on the first optical guide of the first pixel. The image sensor may also include a micro lens formed on the first color filter.

The first light reflection pattern comprises a bottom reflection pattern and a top reflection pattern. The bottom reflection pattern is formed under a boundary area between the first color filter and a color filter that is adjacent to the first color filter, and reflecting light refracted at a first refraction angle, which is calculated from a vertical normal of the first color filter. The top reflection pattern is formed in the boundary area between the first color filter and the adjacent color filter so as to face the reflection pattern, and reflecting light refracted at a second refraction angle, which is calculated from the normal of the first color filter.

### BRIEF DESCRIPTION OF THE DRAWINGS

Exemplary embodiments will be more clearly understood from the following detailed description of the embodiments taken in conjunction with the accompanying drawings in which:

FIG. 1 is a circuit diagram of a unit pixel of an image sensor, according to an embodiment;

FIG. 2 is a schematic layout of an image sensor according to an embodiment;

FIG. 3 is a cross-section taken along line of FIG. 2;

FIG. 4A is an enlarged view of an area A illustrated in FIG. 3;

FIG. 4B is an enlarged view of an area B illustrated in FIG. 3; and

FIG. 5 is a schematic block diagram of an image sensing system including the image sensor according to the embodiment illustrated in FIGS. 1 through 4, according to an embodiment.

### DETAILED DESCRIPTION OF EXAMPLE EMBODIMENTS

Example embodiments of the present invention will be more clearly understood from the detailed description taken in conjunction with the accompanying drawings.

Various example embodiments of the present invention will now be described more fully with reference to the accompanying drawings in which some example embodiments of the invention are shown. In the drawings, the thicknesses of layers and regions may be exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

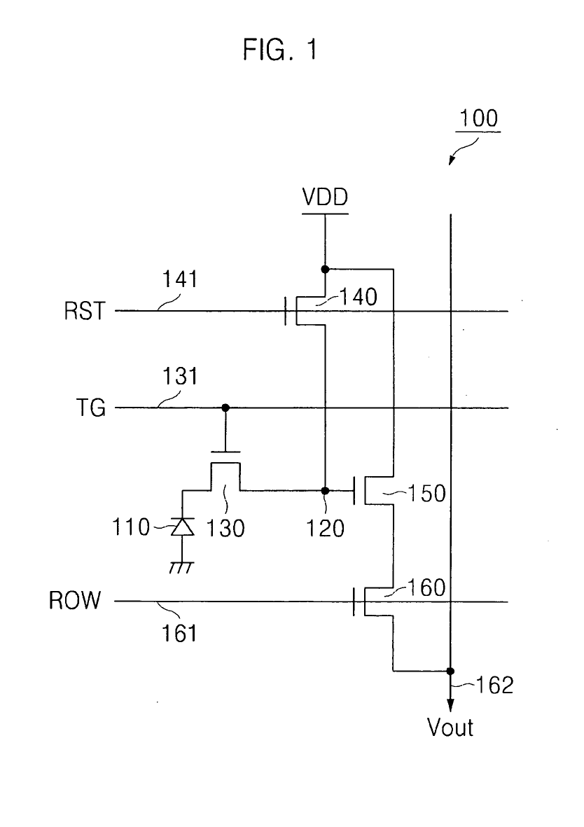

FIG. 1 is a circuit diagram of an image sensor including a unit pixel 100 according to some embodiments. Referring to FIG. 1, the unit pixel 100 includes a photoelectric conversion unit 110 (for example, a photodiode), a charge detection unit 120, a charge transmission unit 130, a reset unit 140, an amplification unit 150, and a selection unit 160. In the present embodiment, the unit pixel 100 includes four transistors 130, 140, 150, and 160. However, the unit pixel 100 may include N (where N is a natural number, for example, 3 or 5) transistors.

The photoelectric conversion unit 110 may absorb incident rays or incident light and accumulate charges corresponding to the intensity of radiation. The photoelectric conversion unit 110 may be a photo diode, a photo transistor, a photo gate, or a pinned photo diode (PPD).

A floating diffusion (FD) region may be used as the charge detection unit 120. The charge detection unit 120 may receive the accumulated charges from the photoelectric conversion unit 110 through the charge transmission unit 130. Since the charge detection unit 120 has parasitic capacitance, charges may be accumulatively stored in the charge detection unit 120. The charge detection unit 120 may be electrically connected to a gate of the amplification unit 150 and may control an operation of the amplification unit 150.

The charge transmission unit 130 may transmit the charges from the photoelectric conversion unit 110 to the charge detection unit 120. The charge transmission unit 130 is generally made up of one transistor and may be controlled by a charge transmission signal TG.

The reset unit 140 may periodically reset the charge detection unit 120. A source of the reset unit 140 is connected to the charge detection unit 120, and a drain thereof is connected to a power source Vdd. The reset unit 140 may be driven in response to a reset signal RST.

The amplification unit 150 may be combined with a static current source (not shown) located outside (or inside) the unit pixel 100 so as to serve as a source follower buffer amplifier. A voltage which varies in response to a voltage of the charge detection unit 120 may be output to a vertical signal (or column line) line 162. A source of the amplification unit 150 is connected to a drain of the selection unit 160, and a drain of the amplification unit 150 is connected to the power source Vdd.

The selection unit 160 may select the unit pixel 100 which is to be read in units of rows. The selection unit 160 is driven in responds to a selection signal ROW. A source of the selection unit 160 is connected to the vertical signal line 162.

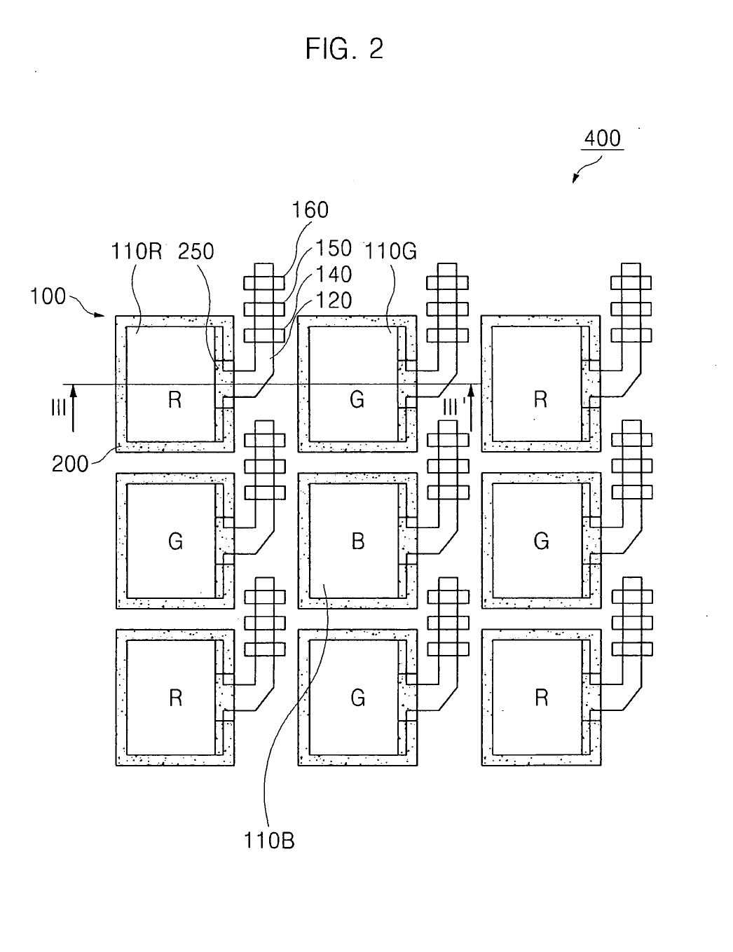

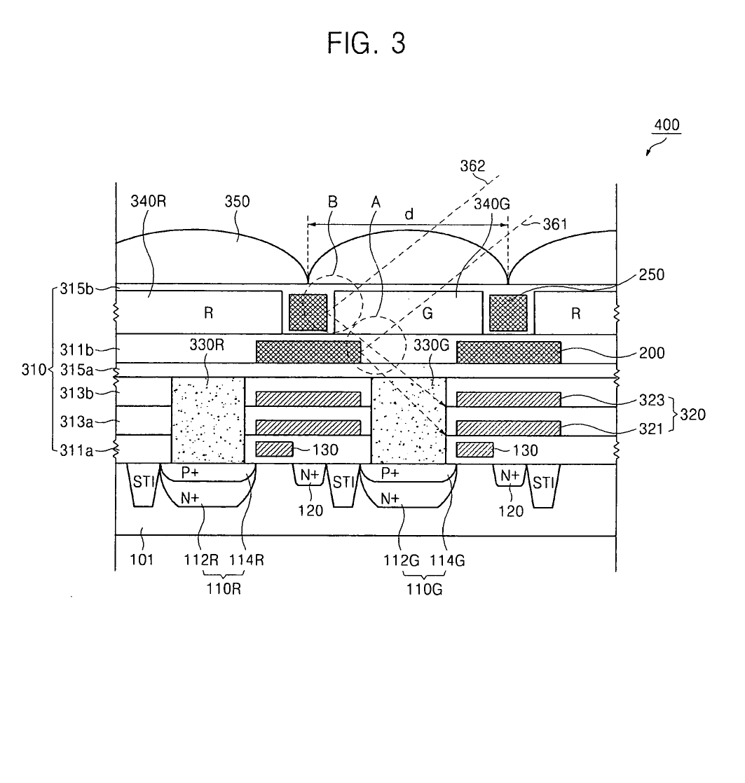

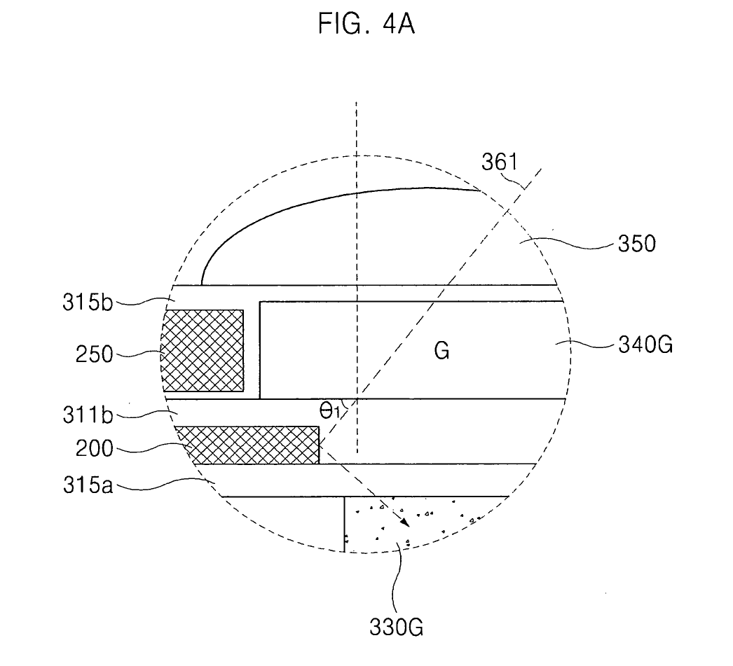

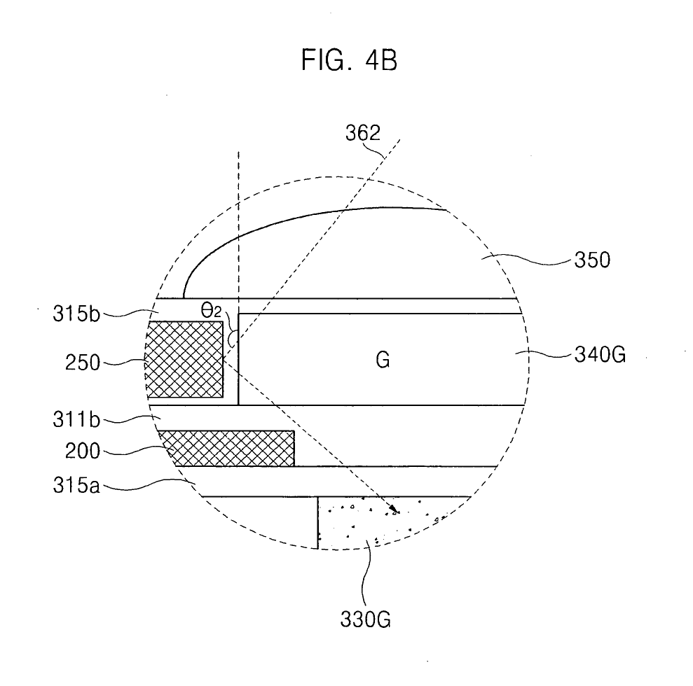

The image sensor 400 according to some embodiments will now be described with reference to FIGS. 2 and 3. FIG. 2 illustrates a schematic layout of the image sensor 400 according to some embodiments. FIG. 3 illustrates a cross-section taken along line of FIG. 2. FIG. 4A is an enlarged view of an area A illustrated in FIG. 3. FIG. 4B is an enlarged view of an area B illustrated in FIG. 3.

The image sensor 400 may include a plurality of the unit pixels 100 laid out in a matrix form and may convert an optical image into an electrical signal. Light incident from an external source passes through color filters and reaches photoelectric conversion units (for example, photo diodes), and thus charges may be accumulated to correspond to incident light corresponding to wavelengths in a predetermined region. In particular, although the color filters in the present embodiment may be arranged in a Bayer pattern as illustrated in FIG. 2, the present embodiment is not limited to this arrangement.

Referring to FIGS. 2 and 3, the image sensor 400 includes a plurality of the unit pixels 100, for example, a first pixel and a second pixel. The first and second pixels may include a photoelectric conversion unit 110R, 110G, or 110B, the charge detection unit 120, the charge transmission unit 130, a dielectric layer structure 310, a wiring pattern 320, light-reflection patterns 200 and 250, a color filter 340R or 340G, and a micro lens 350 which are sequentially formed on a semiconductor substrate 101.

Isolation regions are formed in the semiconductor substrate 101 so as to define active regions. The isolation regions may be Field OXide (FOX) or shallow trench isolation (STI) regions which may be formed using a LOCal Oxidation of Silicon (LOCOS) method.

In each active region defined in the semiconductor substrate 101 by the isolation regions, a plurality of photoelectric conversion units, such as units 110R, 110G, and 110B, capable of accumulating charges generated due to absorption of light energy incident from an external source may be formed. In other words, at least one active region may be defined by the isolation regions formed in the semiconductor substrate 101, and each of the active regions may include the photoelectric conversion unit 110R, 110G, or 110B of the first pixel and the photoelectric conversion unit 110R, 110G, or 110B of the second pixel.

The photoelectric conversion units 110R and 110G may include N-type photo diodes 112R and 112G, respectively, and P+-type pinning layers 114R and 114G, respectively.

In each of the active regions of the semiconductor substrate 101, the charge detection units 120 may be formed, transistors corresponding to the charge transmission units 130, the reset units 140, the amplification units 150, and the selection units 160 may be formed. The dielectric layer structure 310, (for example a first interlayer dielectric layer 311a) may be formed on the photoelectric conversion units 110R, 110G, and 110B and the charge transmission units 130 to cover the entire surface of the semiconductor substrate 101 and to fill empty spaces not occupied by transistors. The first interlayer dielectric layer 311a may be an oxide layer (for example, a silicon dioxide (SiO2) layer), or a combination of the oxide layer and a nitride layer.

The wiring patterns 320 may be formed on the first interlayer dielectric layer 311a. Each of the wiring patterns 320 may be a single layer or a plurality of layers. In the present embodiment, each of the wiring patterns 320 includes a first wiring pattern 321 and a second wiring pattern 323.

The first wiring patterns 321 may be formed on the first interlayer dielectric layer 311a. The first wiring patterns 321 may be formed of aluminum (Al), tungsten (W), or copper (Cu) and may be formed in peripheral circuit regions. The peripheral circuit regions denote regions not occupied by the photoelectric conversion units 110R, 110G, and/or 110B on the semiconductor substrate 101. Regions occupied by the photoelectric conversion units 110R, 110G, and/or 110B on the semiconductor substrate 101 may be defined as light-receiving regions.

A first metal-interlayer dielectric layer 313a may be formed on the first wiring patterns 321 or on the first interlayer dielectric layer 311a. The first metal-interlayer dielectric layer 313a may be an oxide layer or a combination of the oxide layer and a nitride layer. The second wiring patterns 323 may be formed on the first metal-interlayer dielectric layer 313a. The second wiring patterns 323 may be arranged over the first wiring patterns 321 so as to face each other, and may be connected to the first wiring patterns 321 through via holes (not shown). The second wiring patterns 323 may be formed of the same material as the material used to form the first wiring patterns 321, for example, Al, W, or Cu.

A second metal-interlayer dielectric layer 313b may be formed on the second wiring patterns 323 or on the first metal-interlayer dielectric layer 313a. The second metal-interlayer dielectric layer 313b may be formed of the same material as the material used to form the first metal-interlayer dielectric layer 313a, for example, the second metal-interlayer dielectric layer 313b may be an oxide layer, or a combination of the oxide layer and a nitride layer.

The first and second metal-interlayer dielectric layers 313a and 313b may be formed of flowable oxide (FOX), high density plasma (HDP), Tonen SilaZene (TOSZ), spin on glass (SOG), undoped silica glass (USG), or the like. Desired (or alternatively predetermined) regions of the dielectric layer structure 310, namely, respective desired (or alternatively predetermined) regions of the first interlayer dielectric layer 311a and the first and second metal-interlayer dielectric layers 313a and 313b, may be open to form open regions (not shown). Parts of the photoelectric conversion units 110R, 110G, or 110B may be exposed through the open regions.

Light guides 330 may be formed in the opening regions of the dielectric layer structure 310 and may extend from the upper surface of the second metal-interlayer dielectric layer 313b to the upper surfaces of the photoelectric conversion units 110R, 110G, and 110B. The light guides 330 may be formed of a material such that lateral surfaces thereof entirely reflects externally-incident light and may fill the opening regions formed in the dielectric layer structure 310. For example, the light guides 330 may be formed of acryl.

The light guides 330 may include a first light guide 330R and a second light guide 330G. The first and second light guides 330R and 330G may be formed over the active regions of the semiconductor substrate 101 and face their respective photoelectric conversion units 110R and 110G.

One surface of the first light guide 330R may face the upper surface of the first photoelectric conversion unit 110R and the other surface thereof may face a color filter, for example, the first color filter 340R. Therefore, the first light guide 330R may guide light externally incident via the first color filter 340R to the first photoelectric conversion unit 110R corresponding to the first color filter 340R. One surface of the second light guide 330G may face the upper surface of the second photoelectric conversion unit 110G, and the other surface thereof may face a color filter, for example, the second color filter 340G. Therefore, the second light guide 330G may guide light externally incident via the second color filter 340G to the second photoelectric conversion unit 110G corresponding to the second color filter 340G.

The first passivation film 315a may be formed on the upper surface of the second metal-interlayer dielectric layer 313b and the light guides 330R and 330B. The first passivation film 315a may protect the wiring patterns 320, the photoelectric conversion units 110R and 110G, and the light guides 330R and 330B, and may be formed of a material that easily transmit externally-incident light.

The top and bottom light-reflection patterns 200 and 250 may be formed over passivation film 315a. For example, the bottom light-reflection patterns 200, may be formed on the first passivation film 315a. The bottom light-reflection patterns 200 may be arranged over the wiring patterns 320 so as to face each other and under a boundary surface between adjacent color filters 340R and 340G. The top light-refraction pattern 250, which will be described later, may be formed in the boundary space between the adjacent color filters 340R and 340G.

The bottom light-reflection patterns 200 may limit (or alternatively prevent) externally-incident light from being refracted by the micro lenses 350 and the color filters 340R and 340G, which will be described later, and being incident on photoelectric conversion units 110R and 110G or light guides 330R and 330B which are adjacent to respective photoelectric conversion units and or light guides corresponding to the color filters 340R and 340G. For example, the bottom light-reflection pattern 200 may be formed under a boundary surface between the first color filter 340R and the second color filter 340G. The micro lenses 350 may be formed on the upper surfaces of the first and second color filters 340R and 340G, respectively.

In an embodiment, externally-incident light may be refracted due to diffraction while passing through the micro lens 350 and the second color filter 340G. Due to the refraction of the incident light, the incident light passed through the second color filter 340G is not incident on the second photoelectric conversion unit 110G corresponding to the second color filter 340G but is incident on the first photoelectric conversion unit 110R or the first light guide 330R which are respectively adjacent to the second photoelectric conversion unit 110G and the first light guide 330R, thereby generating optical cross-talk.

However, as shown FIG. 3, the bottom light-reflection patterns 200 may reflect the externally-incident light passed through the micro lens 350 and the second color filter 340G so as to be incident on one side of the second light guide 330G.

Referring to FIGS. 3 and 4A, the bottom light-reflection patterns 200 may be formed where the first incident light 361 refracted while passing through the micro lens 350 or the second color filter 340G can be reflected. The bottom light-reflection patterns 200 may be located to reflect the first incident light 361 which is refracted at a first refraction angle θ₁ calculated from a normal which is a vertical direction of the micro lens 350 or the second color filter 340G by using Equation 1:

θ₁=Sin⁻¹(n*λ/d) [Equation 1]

where θ₁ may denote the first refraction angle at which the first incident light 361 passes through the micro lens 350 or the second color filter 340G is refracted, n may denote a natural number, λ may denote the wavelength of light, and d may denote a pitch of the micro lens 350 located on the second color filter 340G. Accordingly, the bottom light-reflection pattern 200 allows light incident through the second color filter 340G to be incident on the second light guide 330G or the second photoelectric conversion unit 110G, both corresponding to the second color filter 340G, thereby reducing optical cross-talk of the image sensor 400.

The bottom light-reflection patterns 200 may be formed of a material capable of reflecting externally-incident light, for example, Al, Cu, or silver (Ag). The second interlayer dielectric layer 311b may be formed on the bottom light-reflection patterns 200 and/or on the first passivation film 315a. The second interlayer dielectric layer 311b may be formed of a material which is the same as the material used to form the first interlayer dielectric layer 311a.

The color filters 340R and 340G may be formed on the second interlayer dielectric layer 311b facing the light guides 330R and 330B or the photoelectric conversion units 110R and 110G. The color filters 340R and 340G may be arranged in a Bayer pattern, including a red color filter, a green color filter, and a blue color filter. At least one color filter 340R and at least one color filter 340G may be formed on respective pixels, namely, on the first pixel where the first light guide 330R and the first photoelectric conversion unit 110R are formed, and on the second pixel where the second light guide 330G and the second photoelectric conversion unit 110G are formed, respectively.

The red color filter 340R may be formed to correspond to the first light guide 330R and the first photoelectric conversion unit 110R. The green color filter 340G, may be formed to correspond to the second light guide 330G and the second photoelectric conversion unit 110G. The top light-reflection patterns 250, may be formed in boundary spaces between adjacent color filters 340R and 340G, for example, between the first color filter 340R and the second color filter 340G.

The top light-reflection patterns 250 may be formed over the first light-reflection patterns 200 so as to face each other. Similar to the bottom light-reflection patterns 200, the top light-reflection patterns 250 may prevent externally incident light from being refracted while passing through the micro lenses 350 and the color filters 340R and 340G and from being incident on photoelectric conversion units 110R and 110G or light guides 330R and 330B which are adjacent to respective photoelectric conversion units and or light guides corresponding to the color filters 340R and 340G. For example, the top light-reflection pattern 250 may be formed in the boundary space between the first color filter 340R and the second color filter 340G. The micro lenses 350 may be formed on the upper surfaces of the first and second color filters 340R and 340G. Externally-incident light may be refracted due to diffraction while passing through the micro lens 350 and the second color filter 340G.

The top light-reflection patterns 250 may reflect the externally-incident light passed through the micro lens 350 and the second color filter 340G so as to be incident on one side of the second light guide 330.

Referring to FIGS. 3 and 4B, the top light-reflection patterns 250 may be formed where the second incident light 362 refracted while passing through the micro lens 350 or the second color filter 340G can be reflected. The top light-reflection patterns 250 may be located to reflect the second incident light 362 which is refracted at a second refraction angle θ₂ calculated from a normal which is a vertical direction of the micro lens 350 or the second color filter 340G by using Equation 2:

θ₂=Sin⁻¹(n*λ/d) [Equation 2]

where θ₂ may denote the second refraction angle at which the second incident light 362 passed through the micro lens 350 or the second color filter 340G is refracted, n may denote a natural number, λ may denote the wavelength of light, and d may denote a pitch of the micro lens 350 located on the second color filter 340G. Accordingly, the top light-reflection pattern 250 allows light incident through the second color filter 340G to be incident on the second light guide 330G or the second photoelectric conversion unit 110G, both corresponding to the second color filter 340G, thereby reducing optical cross-talk of the image sensor 400.

The too light-reflection patterns 250 may be formed of a material which is the same as the material used to form the bottom light-reflection patterns 200, for example, Al, Cu, or Ag. Although the bottom light-reflection patterns 200 and the top light-reflection patterns 250 are included in the image sensor 400 in the present embodiment, the present embodiment is not limited thereto. For example, at least one of the light-reflection patterns 200 and 250 may be formed between adjacent color filters 340R and 340G.

Although in the present embodiment, the bottom light-reflection patterns 200 are formed on the same level and the top light-reflection patterns 250 are formed on the same level, the present embodiment is not limited thereto. For example, the horizontal positions of the top light-reflection patterns 200 and the horizontal positions of the bottom light-reflection patterns 250 may vary according to the positions of the color filters 340R and 340G.

The second passivation film 315b may be formed on the upper surfaces of the color filters 340R and 340G or on the upper surfaces of the top light-reflection patterns 250. The second passivation film 315b may be formed of a material which is the same as the material used to form the first passivation film 315a, and protect the color filters 340R and 340G and the top light-reflection patterns 250.

The micro lenses 350 may be formed on the second passivation film 315b so as to face the first and second color filters 340R and 340G, respectively. The micro lenses 350 may be formed of TMR-based resin or MFR-based resin.

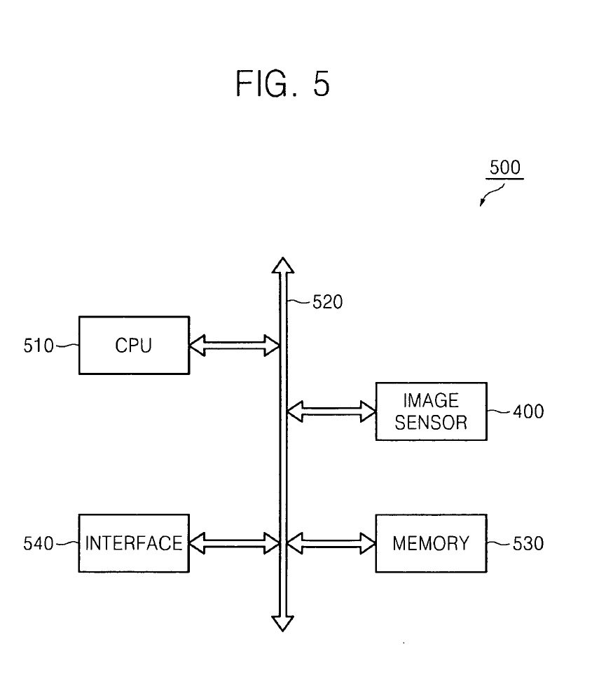

FIG. 5 is a schematic block diagram of an image sensing system 500 including the image sensor 400 described above with reference to FIGS. 1 through 4, according to some embodiments. The image sensing system 500 may be a computer system, a digital camera system, a scanner, a mechanized clock system, a navigation system, a video phone, a management system, an auto focusing system, an operation-monitoring system, an image stabilization system, or the like, but various other systems may be used as the image sensing system 500.

Referring to FIG. 5, the image sensing system 500, which is a computer system, may include a bus 520, a central processing unit (CPU) 510, the image sensor 400, and a memory 530. Although not shown in FIG. 5, the image sensing system 500 may further include an interface 540 that is connected to the bus 520 so as to communicate with the outside. The interface may be an input/output (I/O) interface or a wireless interface.

The CPU 510 may generate a control signal for controlling an operation of the image sensor 400 and provide the control signal to the image sensor 400 via the bus 520.

The image sensor 400 may include an APS array, a row driver, and an analog-to-digital converter (ADC) and may sense light according to the control signal provided from the CPU 510 and convert the light into an electrical signal to thereby generate an image signal. The memory 530 may receive the image signal from the image sensor 400 via the bus 520 and store the image signal.

The image sensor 400 may be integrated with the CPU 510, the memory 530, and the like. In some cases, the image sensor 400 may be integrated with a digital signal processor (DSP). In some instances only the image sensor 400 may be integrated into a separate chip.

An image sensor according to one or more embodiments includes at least one light reflection pattern formed in an area between color filters, for example, in an area corresponding to a light-incidence angle where cross-talk is predicted to occur. Thus, crosstalk caused by incident light diffracted by the color filters can be prevented, thereby reducing light loss and improving the characteristics of the image sensor.

While the embodiments have been particularly shown and described with reference to exemplary embodiments thereof, it will be understood that various changes in form and details may be made therein without departing from the spirit and scope of the following claims.

What is claimed is:

1. An image sensor, comprising:
a first pixel;
at least a first light reflection pattern formed to be adjacent to the first pixel and reflecting incident light to the first pixel corresponding to at least the first light reflection pattern,
wherein the first pixel includes,
a first photoelectric conversion unit formed on a semiconductor substrate and generating charges according to the incident light;
a first color filter formed over the first photoelectric conversion unit; and
a first optical guide located between the first photoelectric conversion unit and the first color filter and guiding light through the first color filter to the first photoelectric conversion unit corresponding to the first color filter; and
wherein at least the first reflection pattern reflects light refracted by the first color filter of the first pixel so that the refracted light is incident on the first optical guide of the first pixel.

2. The image sensor of claim 1, wherein the at least the first light reflection pattern comprises:
a bottom reflection pattern formed under a boundary area between the first color filter and a color filter that is adjacent to the first color filter, and reflecting light refracted at a first refraction angle, which is calculated from a vertical normal of the first color filter; and
a top reflection pattern formed in the boundary area between the first color filters and the adjacent color filter so as to face the first reflection pattern, and reflecting light refracted at a second refraction angle, which is calculated from the vertical normal of the first color filter.

3. The image sensor of claim 2, further comprising:
a micro lens formed on the first color filter,
wherein the bottom reflection pattern is formed at a place capable of reflecting the light refracted at the first refraction angle that satisfies θ1=Sin⁻¹(n*λ/d), where θ1 denotes the first refraction angle, n denotes a natural number, λ denotes a wavelength of the light, and d denotes a pitch of each of the micro lenses.

4. The image sensor of claim 2, further comprising:
a micro lens formed on the first color filter,
wherein the top reflection pattern is formed at a place capable of reflecting the light refracted at the second refraction angle that satisfies θ2=Sin⁻¹(n*λ/d), where θ2 denotes the second refraction angle, n denotes a natural number, λ denotes a wavelength of the light, and d denotes a pitch of each of the micro lenses.

5. The image sensor of claim 1, wherein at least the first light reflection pattern includes one of consisting of aluminum (Al), tungsten (W), and silver (Ag).

6. The image sensor of claim 1, further comprising:
a second pixel formed to be adjacent to the first pixel; and
at least a second light reflection formed between the first and second pixels and reflecting incident light to one of the first pixel and second pixel corresponding to at least the second light reflection pattern,
wherein the second pixel includes,
a second photoelectric conversion unit formed on a semiconductor substrate and generating charges according to the incident light;
a second color filter formed over the second photoelectric conversion unit; and
a second optical guide located between the second photoelectric conversion unit and the second color filter and guiding light through the second color filter to the second photoelectric conversion unit corresponding to the second color filter; and
wherein at least the second reflection pattern reflects light refracted by the second color filter of the second pixel so that the refracted light is incident on the second optical guide of the second pixel.

7. An image sensing system comprising:
an image sensor sensing light and generating an image signal from the sensed light;
a central processing unit (CPU) controlling operations of the image sensor; and
a memory storing the image signal received from the image sensor controlled by the CPU,
wherein the image sensor of the image sensing system comprises:
a first pixel; and
at least a first light reflection pattern formed to be adjacent to the first pixel and reflecting incident light to the first pixel corresponding to at least the first light reflection pattern,
wherein the first pixel includes,
a first photoelectric conversion unit formed on a semiconductor substrate and generating charges according to the incident light;
a first color filter formed over the first photoelectric conversion unit; and
a first optical guide located between the first photoelectric conversion unit and the first color filter and guiding light through the first color filter to the first photoelectric conversion unit corresponding to the first color filter; and
wherein at least the first reflection pattern reflects light refracted by the first color filter of the first pixel so that the refracted light is incident on the first optical guide of the first pixel.

8. The image sensing system of claim 7, wherein the at least the first light reflection pattern comprises:
a bottom reflection pattern formed under a boundary area between the first color filter and a color filter that is adjacent to the first color filter, and reflecting light refracted at a first refraction angle, which is calculated from a vertical normal of the first color filter; and
a top reflection pattern formed in the boundary area between the first color filters and the adjacent color filter so as to face the first reflection pattern, and reflecting light refracted at a second refraction angle, which is calculated from the vertical normal of the first color filter.

9. The image sensing system of claim 8, further comprising:
a micro lens formed on the first color filter,
wherein the bottom reflection pattern is formed at a place capable of reflecting the light refracted at the first refraction angle that satisfies θ1=Sin⁻¹(n*λ/d), where θ1 denotes the first refraction angle, n denotes a natural number, λ denotes a wavelength of the light, and d denotes a pitch of each of the micro lenses.

10. The image sensing system of claim 8, further comprising:
a micro lens formed on the first color filter,
wherein the top reflection pattern is formed at a place capable of reflecting the light refracted at the second refraction angle that satisfies θ2=Sin⁻¹(n*λ/d), where θ2 denotes the second refraction angle, n denotes a natural number, λ denotes a wavelength of the light, and d denotes a pitch of each of the micro lenses.

11. The image sensor of claim 6, wherein the at least one light reflection pattern includes one of the consisting of aluminum (Al), tungsten (W), and silver (Ag).

12. The image sensing system of claim 7, further comprising:
a second pixel formed to be adjacent to the first pixel; and
at least a second light reflection formed between the first and second pixels and reflecting incident light to one of the first pixel and second pixel corresponding to at least the second light reflection pattern,
wherein the second pixel includes,
a second photoelectric conversion unit formed on a semiconductor substrate and generating charges according to the incident light;
a second color filter formed over the second photoelectric conversion unit; and
a second optical guide located between the second photoelectric conversion unit and the second color filter and guiding light through the second color filter to the second photoelectric conversion unit corresponding to the second color filter; and
wherein at least the second reflection pattern reflects light refracted by the second color filter of the second pixel so that the refracted light is incident on the second optical guide of the second pixel.
